(19) United States
(12) Patent Application Publication
(10) Pub. No.: US 2026/0268824 A1
(43) Pub. Date: Sep. 10, 2026

(54) GATE DRIVING CIRCUIT AND DISPLAY PANEL

(71) Applicant: BOE TECHNOLOGY GROUP CO., LTD., Beijing (CN)

(72) Inventor: Ting LI, Beijing (CN)

(73) Assignee: BOE TECHNOLOGY GROUP CO., LTD., Beijing (CN)

(21) Appl. No.: 19/491,406

(22) PCT Filed: May 21, 2024
(86) PCT No.: PCT/CN2024/094442

§ 371 Date: Dec. 9, 2025

(30) Foreign Application Priority Data
Jun. 19, 2023 (CN) 202310729566.7

(51) Int. Cl. G09G 3/20; G11C 19/28

(52) U.S. Cl. CPC G09G 3/20; G11C 19/28; G09G 2310/0267; G09G 2310/0286; G09G 2310/08; G09G 2330/04

(57) ABSTRACT

A gate driving circuit and a display panel are disclosed. The gate driving circuit includes multiple repeating units, each including cascaded first and second shift-register units. In the same repeating unit, the feedback terminal of the first shift-register unit is connected to the first output-terminal of the second shift-register unit, the first output-terminal of the first shift-register unit is connected to the input-terminal of the second shift-register unit, and the second output-terminal of the first shift-register unit is connected to the feedback terminal of the second shift-register unit. In the same shift-register unit, the input selection module performs input using the signal from the input terminal or the feedback terminal, in response to the signal from the first or second selection terminal. The output selection module performs output through either the first or second output terminal, in response to the signal from the first or second selection terminal.

### CROSS-REFERENCE TO RELATED APPLICATIONS

The present disclosure a U.S. National Stage of International Application No. PCT/CN2024/094442, filed on May 21, 2024, and claims the priority of Chinese patent application No. 202310729566.7, filed on Jun. 19, 2023, titled “GATE DRIVING CIRCUIT AND DISPLAY PANEL”, the entire content of each are incorporated herein by reference.

### TECHNICAL FIELD

The present disclosure relates to a field of display technology, and more particularly, to a gate driving circuit and a display panel.

### BACKGROUND

The current market demands higher PPI (pixels per inch) and a narrow bezel user experience, making it difficult for current designs to continue shrinking. Meanwhile, as resolution continues to increase, the number of GOA (Gate Driver on Array) groups also increases, indirectly affecting the stability of the signal. Additionally, the increase in the number of components raises an RC load of a circuit, thereby affecting the reliability of the product.

### SUMMARY

The objective of the present disclosure is to overcome the deficiencies of the related art and provide a gate driving circuit and a display panel.

According to a first aspect of the present disclosure, a gate driving circuit is provided and includes a plurality of repeating units, where the repeating unit include a first shift register unit and a second shift register unit connected in cascade, each of the first shift register unit and the second shift register unit include an input selection module, an output selection module, one input terminal, one feedback terminal, and two output terminals, and the first shift register unit and the second shift register unit are each respectively connected to a first clock signal terminal and a second clock signal terminal; in a same repeating unit, the feedback terminal of the first shift register unit is connected to a first output terminal of the second shift register unit, a first output terminal of the first shift register unit is connected to the input terminal of the second shift register unit, and a second output terminal of the first shift register unit is connected to the feedback terminal of the second shift register unit; in two adjacent repeating units, a second output terminal of the second shift register unit in a previous repeating unit is connected to the input terminal of the first shift register unit in a next repeating unit; in a same shift register unit, the input selection module is connected to the input terminal, a first selection terminal, a second selection terminal, and the feedback terminal; and the input selection module is configured to use a signal of the input terminal for input in response to a signal of the first selection terminal or to use a signal of the feedback terminal for input in response to a signal of the second selection terminal; the output selection module is connected to the first output terminal, the second output terminal, the first selection terminal, and the second selection terminal, and the output selection module is configured to perform an output operation through the first output terminal in response to the signal of the first selection terminal, or to perform an output operation through the second output terminal in response to the signal of the second selection terminal; where in the same shift register unit, the signal of the first selection terminal and the signal of the second selection terminal are of opposite polarities, and conduction levels of the first selection terminals of two shift register units in the same repeating unit are partially overlapped with each other, and conduction levels of the second selection terminals of the two shift register units in the same repeating unit are partially overlapped with each other; a signal of the first clock signal terminal is inverted to a signal of the second clock signal terminal, and signals of the first clock signal terminal and the second clock signal terminal of the first shift register unit are correspondingly inverted to signals of the first clock signal terminal and the second clock signal terminal of the second shift register unit.

In an exemplary embodiment of the present disclosure, in any one of the repeating units, the first output terminal of the first shift register unit is served as an nth output terminal of the gate driving circuit, and the second output terminal of the first shift register unit is served as an (n+2)th output terminal of the gate driving circuit; the first output terminal of the second shift register unit is served as an (n+1)th output terminal of the gate driving circuit, and the second output terminal of the second shift register unit is served as an (n+3)th output terminal of the gate driving circuit, where n is a natural number greater than or equal to 1.

In an exemplary embodiment of the present disclosure, when the first selection terminal of the first shift register unit outputs a conduction level with a duration of T, the first selection terminal of the second shift register unit sequentially outputs a conduction level with a duration of T/2 and a non-conduction level with a duration of T/2; when the second selection terminal of the first shift register unit outputs a conduction level with a duration of T, the second selection terminal of the second shift register unit sequentially outputs a non-conduction level with a duration of T/2 and a conduction level with a duration of T/2.

In an exemplary embodiment of the present disclosure, a duration of a conduction level of the first clock signal terminal and a duration of a conduction level of the second clock signal terminal are t, where t=T/2.

In an exemplary embodiment of the present disclosure, when the input terminal of the first shift register unit is at a conduction level, the first clock signal terminal of the first shift register unit is at a conduction level, and the second clock signal terminal of the first shift register unit is at a non-conduction level.

In an exemplary embodiment of the present disclosure, the input selection module is further connected to a first node, and the input selection module is further configured to transmit the signal of the input terminal to the first node in response to the signal of the first selection terminal, or to transmit the signal of the feedback terminal to the first node in response to the signal of the second selection terminal; and the output selection module is further connected to a fifth node, and the output selection module is further configured to transmit a signal of the fifth node to the first output terminal in response to the signal of the first selection terminal, or to transmit a signal of the fifth node to the second output terminal in response to the signal of the second selection terminal.

In an exemplary embodiment of the present disclosure, each of the input selection module and the output selection module includes a transistor, and a polarity of each transistor is identical.

In an exemplary embodiment of the present disclosure, the input selection module includes: a first selection transistor, with a first electrode connected to the input terminal, a second electrode connected to the first node, and a gate connected to the first selection terminal, where the first selection transistor is configured to transmit the signal of the input terminal to the first node in response to the signal of the first selection terminal; a second selection transistor, with a first electrode connected to the feedback terminal, a second electrode connected to the first node, and a gate connected to the second selection terminal, where the second selection transistor is configured to transmit the signal of the feedback terminal to the first node in response to the signal of the second selection terminal; where the output selection module includes: a third selection transistor, with a first electrode connected to the fifth node, a second electrode connected to the first output terminal, and a gate connected to the first selection terminal, where the third selection transistor is configured to transmit the signal of the fifth node to the first output terminal in response to the signal of the first selection terminal; a fourth selection transistor, with a first electrode connected to the fifth node, a second electrode connected to the second output terminal, and a gate connected to the second selection terminal, where the fourth selection transistor is configured to transmit the signal of the fifth node to the second output terminal in response to the signal of the second selection terminal; where the first selection transistor, the second selection transistor, the third selection transistor and the fourth selection transistor are all P-type transistors.

In an exemplary embodiment of the present disclosure, the first shift register unit and the second shift register unit each include: an input module, connected to a first node, a third node, and the first clock signal terminal, where the input module is configured to transmit a signal of the first node to the third node in response to the signal of the first clock signal terminal; a first control module, connected to a second node and the first clock signal terminal, and configured to receive a first level signal, where the first control module is configured to pull down the second node using the first level signal in response to the signal of the first clock signal terminal; a second control module, connected to the second node, the third node, and the first clock signal terminal, where the second control module is configured to pull up the second node using the signal of the first clock signal terminal in response to a signal of the third node; a reset module, connected to the second node, the third node, and the second clock signal terminal, and configured to receive a second level signal, where the reset module is configured to reset the third node using the second level signal in response to a signal of the second node and the signal of the second clock signal terminal; a protection module, connected to the third node and a fourth node, and configured to receive the first level signal, where the protection module is configured to transmit the signal of the third node to the fourth node in response to the first level signal, or to be turned off in response to a voltage difference between the first level signal and a signal of the fourth node; a first output module, connected to the second node, the first output terminal and the second output terminal, and receiving the second level signal, where the first output module is configured to transmit the second level signal to the first output terminal and the second output terminal in response to the signal of the second node; a second output module, connected to a fifth node, the fourth node, and the second clock signal terminal, where the second output module is configured to transmit the signal of the second clock signal terminal to the fifth node in response to the signal of the fourth node.

In an exemplary embodiment of the present disclosure, the input module, the first control module, the second control module, the reset module, the protection module, the first output module, and the second output module each include a transistor, and a polarity of each transistor is identical.

In an exemplary embodiment of the present disclosure, the input module includes: a first transistor, with a first electrode connected to the first node, a second electrode connected to the third node, and a gate connected to the first clock signal terminal, where the first transistor is configured to transmit the signal of the first node to the third node in response to the signal of the first clock signal terminal; a first control transistor, with a first electrode configured to receive the first level signal, a second electrode connected to the second node, and a gate connected to the first clock signal terminal, where the first control transistor is configured to transmit the first level signal to the second node in response to the signal of the first clock signal terminal; where the second control module includes: a second control transistor, with a first electrode connected to the second node, a second electrode connected to the first clock signal terminal, and a gate connected to the third node, where the second control transistor is configured to pull down the second node using the signal of the first clock signal terminal in response to the signal of the third node; where the reset module includes: a first reset transistor, with a first electrode connected to and configured to receive the second level signal, a second electrode connected to a sixth node, and a gate connected to the second node, where the first reset transistor is configured to transmit the second level signal to the sixth node in response to the signal of the second node; a second reset transistor, with a first electrode connected to the third node, a second electrode connected to the sixth node, and a gate connected to the second clock signal terminal, where the second reset transistor is configured to transmit, in response to the signal of the second clock signal terminal, a signal of the sixth node to the third node to reset the third node; where the protection module includes: a second transistor, with a first electrode connected to the third node, a second electrode connected to the fourth node, and a gate configured to receive the first level signal, where the second transistor is configured to transmit the signal of the third node to the fourth node in response to the first level signal, or to be turned off in response to the voltage difference between the first level signal and the signal of the fourth node; where the first output module includes: a first output transistor, with a first electrode configured to receive the second level signal, a second electrode connected to the first output terminal, and a gate connected to the second node, where the first output transistor is configured to transmit the second level signal to the first output terminal in response to the signal of the second node; a second output transistor, with a first electrode configured to receive the second level signal, a second electrode connected to the second output terminal, and a gate connected to the second node, where the second output transistor is configured to transmit the second level signal to the second output terminal in response to the signal of the second node; where the second output module includes: a third output transistor, with a first electrode connected to the fifth node, a second electrode connected to the second clock signal terminal, and a gate connected to the fourth node, where the third output transistor is configured to transmit the signal of the second clock signal terminal to the fifth node in response to the signal of the fourth node.

In an exemplary embodiment of the present disclosure, the first transistor, the first control transistor, the second control transistor, the first reset transistor, the second reset transistor, the second transistor, the first output transistor, the second output transistor, and the third output transistor are all P-type transistors.

In an exemplary embodiment of the present disclosure, the first shift register unit and the second shift register unit each further include: a first storage module, connected to a second node and configured to receive a second level signal, where the first storage module is configured to maintain stability of a potential of the second node; a second storage module, connected to a fourth node and a fifth node, where the second storage module is configured to bootstrap the fourth node when a polarity for a signal of the fifth node and a polarity for a signal of the fourth node are identical.

In an exemplary embodiment of the present disclosure, the first storage module includes: a first capacitor, with a first terminal connected to the second node, and a second terminal configured to receive the second level signal; where the second storage module includes: a second capacitor, with a first terminal connected to the fourth node and a second terminal connected to the fifth node.

According to a second aspect of the present disclosure, a display panel is provided and includes the gate driving circuit according to any embodiment of the present disclosure.

In the gate driving circuit of the present disclosure, by cascading each shift register unit according to the above relationships, an output of four rows of gate signals from a single repeating unit may be achieved. Compared to the related art, this simplifies the circuit structure of the gate driving circuit, thus reducing the RC load in the circuit. Additionally, the space saved by simplifying the circuit structure also reduces the size of the side bezel, improving the competitiveness of the product.

It should be understood that the above general description and the detailed description below are merely exemplary and explanatory, and do not limit the scope of the present disclosure.

### BRIEF DESCRIPTION OF THE DRAWINGS

The drawings herein are incorporated into the specification and form part of this specification, showing embodiments that conform to the present disclosure and are used together with the specification to explain the principles of the present disclosure. It is obvious that the drawings in the following description are merely some embodiments of the present disclosure, and these skilled in the art could derive other drawings based on these without any inventive effort.

FIG. 1 is a block diagram of a gate driving circuit according to an embodiment of the present disclosure;

FIG. 2 is a schematic diagram of a gate driving circuit according to another embodiment of the present disclosure;

FIG. 3 is a block diagram of a shift register unit in FIG. 1;

FIG. 4 is a schematic diagram of a shift register unit in another embodiment of the present disclosure;

FIG. 5 is a timing diagram of each node in FIG. 3;

FIG. 6 is an equivalent circuit diagram of a first shift register unit in a first phase;

FIG. 7 is an equivalent circuit diagram of a second shift register unit in a first phase;

FIG. 8 is an equivalent circuit diagram of a first shift register unit in a second phase;

FIG. 9 is an equivalent circuit diagram of a second shift register unit in a second phase;

FIG. 10 is an equivalent circuit diagram of a first shift register unit in a third phase;

FIG. 11 is an equivalent circuit diagram of a second shift register unit in a third phase;

FIG. 12 is an equivalent circuit diagram of a first shift register unit in a fourth phase;

FIG. 13 is an equivalent circuit diagram of a second shift register unit in a fourth phase;

FIG. 14 is an equivalent circuit diagram of a first shift register unit in a fifth phase; and

FIG. 15 is an equivalent circuit diagram of a second shift register unit in a fifth phase.

### DETAILED DESCRIPTION

The exemplary embodiments will now be described more fully with reference to the drawings. However, the exemplary embodiments may be implemented in various forms and should not be understood as limited to the embodiments described herein; instead, the embodiments are provided to enable the present disclosure to be comprehensive and complete, and to fully convey the concepts of the exemplary embodiments to those skilled in the art. The Same reference numerals in the drawings refer to the same or similar structures, and thus detailed descriptions thereof will be omitted. Furthermore, the drawings are merely illustrative of the present disclosure and are not necessarily drawn to scale.

Although relative terms such as “upper” and “lower” are used in this specification to describe the relative relationship of one component to another in the drawings, these terms are used in this specification merely for convenience, based on the direction shown in the example in the drawings. It is understood that if the device in the drawings is flipped upside down, the component described as being “upper” will become the component that is “lower.” When a certain structure is “on” another structure, it may refer to a structure being integrally formed on another structure, or a structure being “directly” placed on another structure, or a structure being “indirectly” placed on another structure through another structure.

The terms “a”, “an”, “the”, “said”, and “at least one” are used to indicate the presence of one or more elements/components/etc. ; the terms “including” and “having” are used to indicate an open-ended inclusion and refer to the possibility of additional elements/components/etc. beyond those listed; the terms “first”, “second”, “third”, etc., are used merely as labels and are not intended to limit the quantity of the objects they refer to.

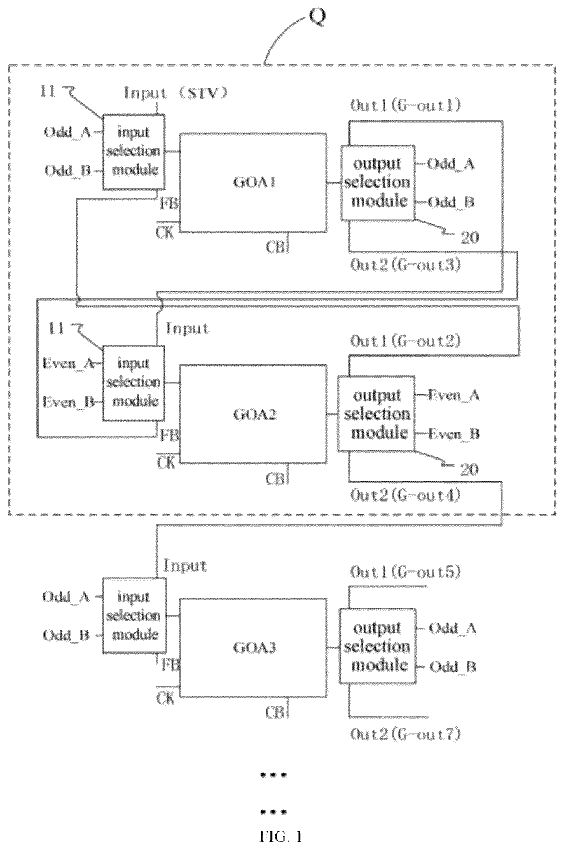

FIG. 1 is a block diagram of a gate driving circuit according to an embodiment of the present disclosure. As shown in FIG. 1, the gate driving circuit may include a plurality of repeating units Q, the repeating unit Q includes a first shift register unit GOA1 and second shift register unit GOA2 connected in cascade. The first shift register unit GOA1 and the second shift register unit GOA2 each include an input selection module 11, an output selection module 20, one input terminal Input, one feedback terminal FB, and two output terminals. In the same repeating unit Q, the feedback terminal FB of the first shift register unit GOA1 is connected to the first output terminal Out1 of the second shift register unit GOA2, the first output terminal Out1 of the first shift register unit GOAL is connected to the input terminal Input of the second shift register unit GOA2, and the second output terminal Out2 of the first shift register unit GOAL is connected to the feedback terminal FB of the second shift register unit GOA2. In two adjacent repeating units Q, the second output terminal Out2 of the second shift register unit GOA2 in the previous repeating unit Q is connected to the input terminal Input of the first shift register unit GOA1 in the next repeating unit Q. In the same shift register unit, the input selection module 11 is connected to the input terminal Input, the first selection terminal Odd_A, the second selection terminal Odd_B, and the feedback terminal FB. The input selection module 11 is configured to either use the signal of the input terminal Input for the input in response to the signal from the first selection terminal Odd_A or use the signal from the feedback terminal FB for the input in response to the signal from the second selection terminal Odd_B. The output selection module 20 is connected to the first output terminal Out1, the second output terminal Out2, the first selection terminal Odd_A, and the second selection terminal Odd_B. The output selection module 20 is configured to output the signal through the first output terminal Out1 in response to the signal from the first selection terminal Odd_A, or output the signal through the second output terminal Out2 in response to the signal from the second selection terminal Odd_B. In the same shift register unit, the signals at the first selection terminal Odd A and the second selection terminal Odd_B are of opposite polarity. The signal at the first clock signal terminal CK is inverted relative to the signal at the second clock signal terminal CB, and the signals at the first clock signal terminal CK and the second clock signal terminal CB of the first shift register unit GOA1 are inverted relative to the corresponding signals at the first clock signal terminal CK and the second clock signal terminal CB of the second shift register unit GOA2.

In the gate driving circuit of the present disclosure, by cascading each shift register unit according to the above relationships, a single repeating unit Q outputting four rows of gate signals may be achieved. Compared to the related art, this simplifies the circuit structure of the gate driving circuit, thereby reducing the RC load in the circuit. Additionally, the space saved by simplifying the circuit structure also reduces the size of the side bezel, enhancing the product's competitiveness.

The input selection module 11 is connected to the first selection terminal Odd_A and the second selection terminal Odd_B, such that when the first selection terminal Odd A is at a conduction level, the input selection module 11 may use the signal from the input terminal Input to perform the input, i.e., transmit the signal from the input terminal Input to the internal circuit of the shift register unit. When the second selection terminal Odd B is at a conduction level, the input selection module 11 may use the signal from the feedback terminal FB to perform the input, i.e., transmit the signal from the feedback terminal FB to the internal circuit of the shift register unit. Similarly, the output selection module 20 is connected to the first selection terminal Odd_A and the second selection terminal Odd B. When the first selection terminal Odd_A is at a conduction level, the output selection module 20 may perform the output operation through the first output terminal Out1. When the second selection terminal Odd_B is at a conduction level, the output selection module 20 may perform the output operation through the second output terminal Out2. A specific circuit structure of the input selection module 11 and the output selection module 20 may be referred to in the description of subsequent embodiments, and will not be expanded here.

It should be understood that when a certain signal terminal is described as being at a conduction level, it means that a level output from the signal terminal is able to conduct or turn on a circuit structure connected to the signal terminal. Correspondingly, when the level output from a certain signal terminal is at a non-conduction level, it means that the level signal output from the signal terminal is able to control the circuit structure connected to the signal terminal to be turned off.

The signal at the first clock signal terminal CK and the signal at the second clock signal terminal CB are inverted, which means that when the first clock signal terminal CK outputs a high-level signal, the second clock signal terminal CB outputs a low-level signal; or when the first clock signal terminal CK outputs a low-level signal, the second clock signal terminal CB outputs a high-level signal.

It should be noted that the high-level and low-level signals described in the present disclosure refer to two logical states represented by a potential range at the circuit nodes. The high-level may specifically denote a level higher than a common-terminal voltage, and the low-level may specifically denote a level lower than a common-terminal voltage. The specific potential range may be set as needed in a specific application scenario, which is not limited in the present disclosure.

The signals at the first clock signal terminal CK and the second clock signal terminal CB of the first shift register unit GOA1 and the signals at the first clock signal terminal CK and the second clock signal terminal CB of the second shift register unit GOA2 are inverted relative to each other, and that is, the signal at the first clock signal terminal CK of the first shift register unit GOA1 is inverted with respect to the signal at the first clock signal terminal CK of the second shift register unit GOA2, and the signal at the second clock signal terminal CB of the first shift register unit GOA1 is inverted with respect to the signal at the second clock signal terminal CB of the second shift register unit GOA2. For example, when the first clock signal terminal CK of the first shift register unit GOA1 is at a high level, the second clock signal terminal CB of the first shift register unit GOA1 is at a low level, and the first clock signal terminal CK of the second shift register unit GOA2 is at a low level, while the second clock signal terminal CB of the second shift register unit GOA2 is at a high level.

In any repeating unit of the present disclosure, the first output terminal Out1 of the first shift register unit GOA1 is served as the nth output terminal G-out(n) of the gate driving circuit, and the second output terminal Out2 of the first shift register unit GOA1 is served as the (n+2)th output terminal G-out(n+2) of the gate driving circuit. The first output terminal Out1 of the second shift register unit GOA2 is served as the (n+1)th output terminal G-out(n+1) of the gate driving circuit, and the second output terminal Out2 of the second shift register unit GOA2 is served as the (n+3)th output terminal G-out(n+3) of the gate driving circuit, where n is a natural number greater than or equal to 1. That is, the first output terminal Out1 and the second output terminal Out2 of the first shift register unit GOA1 are configured to output the nth row gate signal and the (n+2)th row gate signal, respectively. The first output terminal Out1 and the second output terminal Out2 of the second shift register unit GOA2 are configured to output the (n+1)th row gate signal and the (n+3)th row gate signal, respectively. It may be seen that the same shift register unit is configured to output gate signals to two pixel rows spaced apart by one row in the display region, respectively, in order to drive two sub-pixel rows spaced apart by one row, and thus, one repeating unit Q may sequentially output gate signals for four consecutive rows to sequentially drive four consecutive sub-pixel rows in the display region. Compared to the gate driving circuit in the related art, the gate driving circuit in the present disclosure simplifies the circuit structure that outputs the same number of gate signals, thus saving the space occupied by the gate driving circuit. The saved space is beneficial for reducing the size of the bezel. Furthermore, it may be understood that the gate driving circuit is typically composed of transistors, and by simplifying the circuit structure of the gate driving circuit, the number of transistors used in the gate driving circuit may be reduced, thereby reducing the RC load in the circuit.

The detailed structure of the gate driving circuit of the present disclosure will now be described with reference to the accompanying drawings.

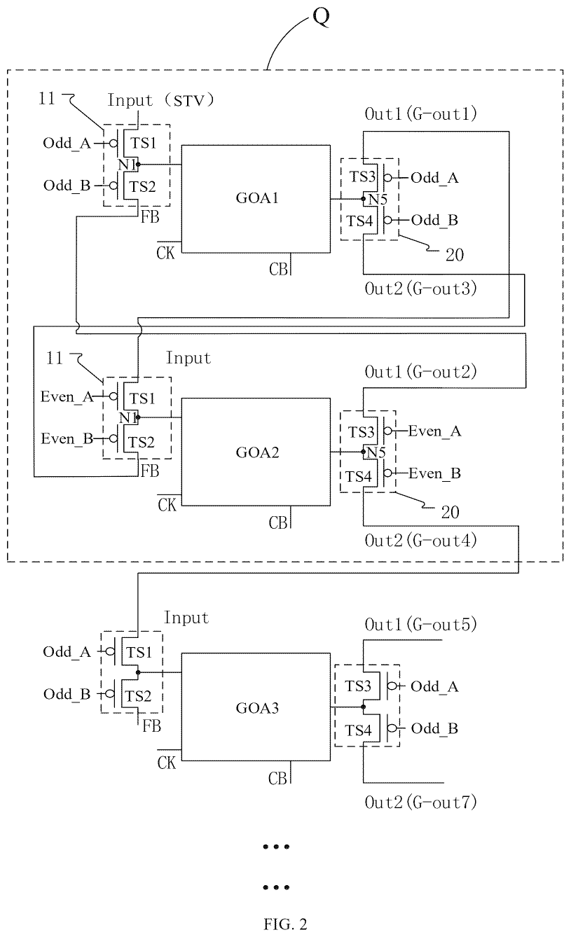

FIG. 2 is a schematic diagram of a gate driving circuit according to another embodiment of the present disclosure. As shown in FIG. 2, both the input selection module and the output selection module may be implemented using transistors. The input selection module may include a first selection transistor TS1 and a second selection transistor TS2. The first electrode of the first selection transistor TS1 is connected to the input terminal, the second electrode of the first selection transistor TS1 is connected to the first node N1, and the gate of the first selection transistor TS1 is connected to the first selection terminal. The first selection transistor TS1 may be configured to transmit the signal from the input terminal to the first node N1 in response to the signal from the first selection terminal. The first electrode of the second selection transistor TS2 is connected to the feedback terminal FB, the second electrode of the second selection transistor TS2 is connected to the first node N1, and the gate of the second selection transistor TS2 is connected to the second selection terminal. The second selection transistor TS2 may be configured to transmit the signal from the feedback terminal FB to the first node N1 in response to the signal from the second selection terminal. The output selection module may include a third selection transistor TS3 and a fourth selection transistor TS4. The first electrode of the third selection transistor TS3 is connected to the fifth node N5, the second electrode of the third selection transistor TS3 is connected to the first output terminal, and the gate of the third selection transistor TS3 is connected to the first selection terminal. The third selection transistor TS3 may be configured to transmit the signal from the fifth node N5 to the first output terminal in response to the signal from the first selection terminal. The first electrode of the fourth selection transistor TS4 is connected to the fifth node N5, the second electrode of the fourth selection transistor TS4 is connected to the second output terminal, and the gate of the fourth selection transistor TS4 is connected to the second selection terminal. The fourth selection transistor TS4 may be configured to transmit the signal from the fifth node N5 to the second output terminal in response to the signal from the second selection terminal.

The first selection transistor TS1 to the fourth selection transistor TS4 are all P-type transistors. When the first selection terminal is at a low level and the second selection terminal is at a high level, the first selection transistor TS1 and the third selection transistor TS3 are turned on, while the second selection transistor TS2 and the fourth selection transistor TS4 are turned off. At the input terminal, the shift register unit uses the signal from the input terminal as the input. At the output terminal, the first output terminal of the shift register unit outputs the signal from the fifth node N5. When the first selection terminal is at a high level, the second selection terminal is at a low level, the first selection transistor TS1 and the third selection transistor TS3 are turned off, while the second selection transistor TS2 and the fourth selection transistor TS4 are turned on. At the input terminal, the signal from the feedback terminal FB is served as the input. At the output terminal, the second output terminal outputs the signal from the fifth node N5.

The shift register unit operates through the specific structure of the above input selection module and the output selection module and the cascading relationship described above. In conjunction with the timing of each node, a repeating unit formed by the first shift register unit GOA1 and the second shift register unit GOA2 may output four rows of gate signals.

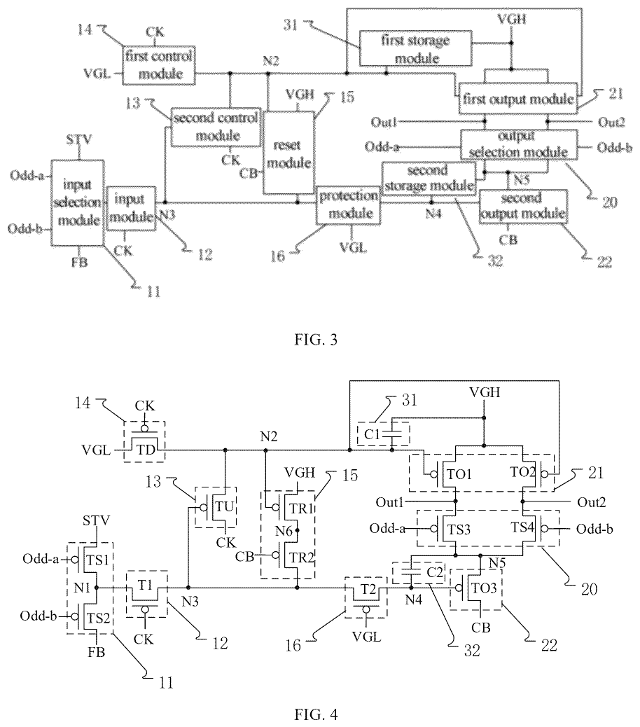

FIG. 3 is a block diagram of a shift register unit in FIG. 1. As shown in FIG. 3, each of the first shift register unit GOA1 and the second shift register unit GOA2 may also include an input module 12, a first control module 14, a second control module 13, a reset module 15, a protection module 16, a first output module 21, a second output module 22, a first storage module 31, and a second storage module 32. The input module 12 is connected to the first node N1, the third node N3, and the first clock signal terminal CK. The input module 12 may be configured to transmit the signal from the first node N1 to the third node N3 in response to the signal from the first clock signal terminal CK. For example, when the first clock signal terminal CK is at a low level, the input module 12 is turned on to transmit the signal from the first node N1 to the third node N3.

The first control module 14 is connected to the second node N2, the first clock signal terminal CK, and receives the first level signal VGL. The first control module 14 may be configured to pull down the second node N2 using the first level signal VGL in response to the signal from the first clock signal terminal CK. The first level signal VGL may be a low-level signal. When the first clock signal terminal CK is at a low level, the first control module 14 is turned on, thus pulling down the second node N2 using the first level signal VGL.

The second control module 13 is connected to the second node N2, the third node N3, and the first clock signal terminal CK. The second control module 13 may be configured to pull up the second node N2 using the signal from the first clock signal terminal CK in response to the signal from the third node N3. The second control module 13 is controlled by the third node N3. When the third node N3 switches to a low level, the second control module 13 is turned on. If the first clock signal terminal CK is at a high-level signal, the second control module 13 may pull up the second node N2. If the first clock signal terminal CK is at a low-level signal, the second control module 13 may pull down the second node N2.

It should be understood that the “pull-up” described in the present disclosure refers to raising a potential at a respective circuit node to a high level, while the “pull-down” refers to lowering a potential at a respective circuit node to a low level. It may be understood that the above “pull-up” and “pull-down” may both be achieved through the directional movement of charge, and thus may specifically be implemented by electronic components with the respective functions or their combinations, which is not limited in the present disclosure.

The reset module 15 is connected to the second node N2, the third node N3, the second clock signal terminal CB, and receives the second level signal VGH. The reset module 15 may be configured to reset the third node N3 by using the second level signal VGH in response to the signal from the second node N2 and the signal from the second clock signal terminal CB. The reset module 15 may perform the reset operation before signal input, for example, when both the second clock signal terminal CB and the second node N2 are at low levels. In this case, the reset module 15 may be controlled to turn on and the second level signal VGH is used to pull up the third node N3, thereby performing the reset operation on the third node N3.

The protection module 16 is connected to the third node N3, the fourth node N4, and receives the first level signal VGL. The protection module 16 may be configured to either transmit the signal from the third node N3 to the fourth node N4 in response to the first level signal VGL, or to be turned off in response to the voltage difference between the first level signal VGL and the signal at the fourth node N4. The protection module 16 may be turned off when the voltage difference between the first level signal VGL and the potential at the fourth node N4 is relatively large, thereby preventing any impact on the potential of the third node N3. In other words, through the protection module 16, the influence of the potential at the fourth node N4 on the potential at the third node N3 may be avoided, maintaining the stability of the potential at the third node N3, which may protect the input module 12, the second control module 13, and the reset module 15 to maintain stable operation.

The first storage module 31 is connected to the second node N2 and receives the second level signal VGH. The first storage module 31 may be configured to maintain the stability of the potential at the second node N2. The second storage module 32 is connected to the fourth node N4 and the fifth node N5. The second storage module 32 may be configured to bootstrap the fourth node N4 when the signals at the fifth node N5 and the fourth node N4 have the same polarity.

FIG. 4 is a schematic diagram of a shift register unit according to another embodiment of the present disclosure. As shown in FIG. 4, the first storage module and the second storage module in the gate driving circuit of the present disclosure may be implemented using storage capacitors and other functional modules may be implemented using transistors. In the exemplary embodiment, the input module 12 may include a first transistor T1, the first electrode of the first transistor T1 is connected to the first node N1, the second electrode of the first transistor T1 is connected to the third node N3, and the gate of the first transistor T1 is connected to the first clock signal terminal CK. The first transistor T1 may be configured to transmit the signal from the first node N1 to the third node N3 in response to the signal from the first clock signal terminal CK. The first control module 14 may include a first control transistor TD. The first electrode of the first control transistor TD receives the first level signal VGL, the second electrode of the first control transistor TD is connected to the second node N2, and the gate of the first control transistor TD is connected to the first clock signal terminal CK. The first control transistor TD may be configured to transmit the first level signal VGL to the second node N2 in response to the signal from the first clock signal terminal CK. The second control module 13 may include a second control transistor TU. The first electrode of the second control transistor TU is connected to the second node N2, the second electrode of the second control transistor TU is connected to the first clock signal terminal CK, and the gate of the second control transistor TU is connected to the third node N3. The second control transistor TU may be configured to pull down the second node N2 using the signal from the first clock signal terminal CK in response to the signal from the third node N3. The reset module 15 may include a first reset transistor TR1 and a second reset transistor TR2. The first electrode of the first reset transistor TR1 is connected to receive the second level signal VGH, the second electrode of the first reset transistor TR1 is connected to the sixth node, and the gate of the first reset transistor TR1 is connected to the second node N2. The first reset transistor TR1 may be configured to transmit the second level signal VGH to the sixth node in response to the signal from the second node N2. The first electrode of the second reset transistor TR2 is connected to the third node N3, the second electrode of the second reset transistor TR2 is connected to the sixth node, and the gate of the second reset transistor TR2 is connected to the second clock signal terminal CB. The second reset transistor TR2 may be configured to transmit the signal from the sixth node to the third node N3 to reset the third node N3 in response to the signal from the second clock signal terminal CB. The protection module 16 may include a second transistor T2. The first electrode of the second transistor T2 is connected to the third node N3, the second electrode of the second transistor T2 is connected to the fourth node N4, and the gate of the second transistor T2 receives the first level signal VGL. The second transistor T2 may be configured to transmit the signal from the third node N3 to the fourth node N4 in response to the first level signal VGL, or to be turned off in response to a voltage difference between the first level signal VGL and the signal at the fourth node N4. The first output module 21 may include a first output transistor TO1 and a second output transistor TO2. The first electrode of the first output transistor TO1 receives the second level signal VGH, the second electrode of the first output transistor TO1 is connected to the first output terminal, and the gate of the first output transistor TO1 is connected to the second node. The first output transistor TO1 may be configured to transmit the second level signal VGH to the first output terminal in response to the signal from the second node. The first electrode of the second output transistor TO2 receives the second level signal VGH, the second electrode of the second output transistor TO2 is connected to the second output terminal, and the gate of the second output transistor TO2 is connected to the second node. The second output transistor TO2 may be configured to transmit the second level signal VGH to the second output terminal in response to the signal from the second node. The second output module 22 may include a third output transistor TO3. The first electrode of the third output transistor TO3 is connected to the fifth node, the second electrode of the third output transistor TO3 is connected to the second clock signal terminal CB, and the gate of the third output transistor TO3 is connected to the fourth node. The third output transistor TO3 may be configured to transmit the signal from the second clock signal terminal CB to the fifth node in response to the signal from the fourth node.

The above-mentioned transistors may all be P-type transistors, for example, P-type low-temperature polysilicon transistors. Of course, in other embodiments, the above-mentioned transistors may also be N-type transistors. The present disclosure uses P-type transistors as an example for illustrative purposes.

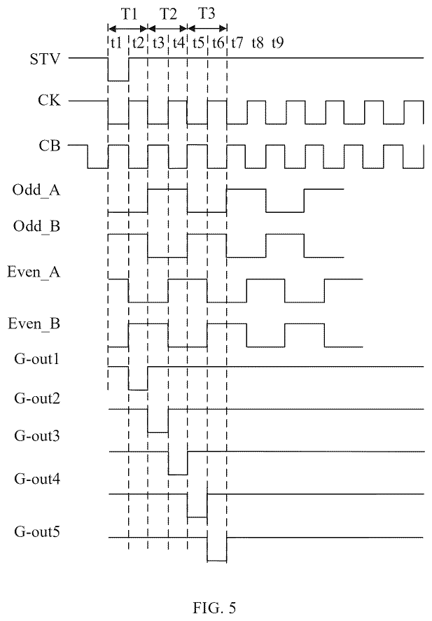

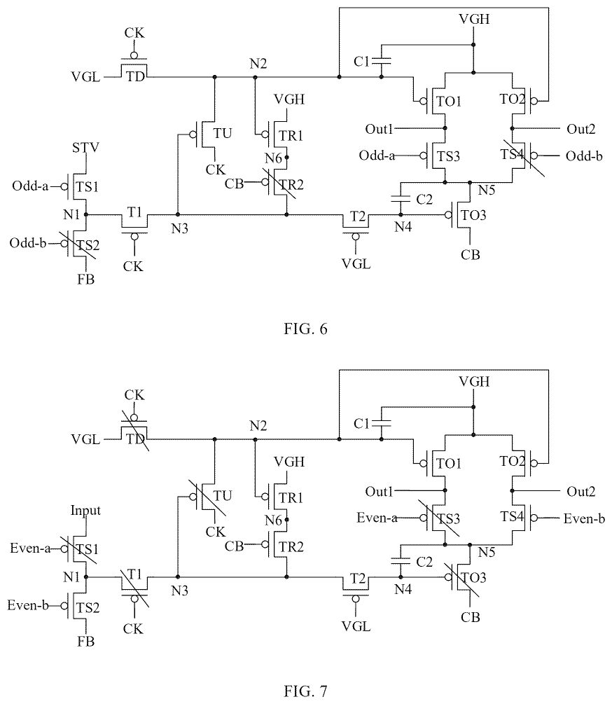

FIG. 5 is a timing diagram of each node in FIG. 3, and FIG. 6 is an equivalent circuit diagram of a first shift register unit in a first phase. FIG. 7 is an equivalent circuit diagram of a second shift register unit in a first phase. It should be understood that, for convenience of explaining the working principle of the shift register unit, FIG. 6 uses the first-stage shift register unit as an example for illustrative purposes. The input terminal of the first-stage shift register unit is connected to a starting signal STV. Additionally, because the first selection terminal and second selection terminal in the first shift register unit GOA1 and the second shift register unit GOA2 are distinguished, Odd_A represents the first selection terminal in the first shift register unit GOA1, Odd_B represents the second selection terminal in the first shift register unit GOA1, Even_A represents the first selection terminal in the second shift register unit GOA2, and Even_B represents the second selection terminal in the second shift register unit GOA2.

Furthermore, as shown in FIG. 5, when the first selection terminal Odd_A of the first shift register unit GOA1 outputs a conduction level with a duration of T, the first selection terminal Even A of the second shift register unit GOA2 sequentially outputs a conduction level and a non-conduction level, each with a duration of T/2. When the second selection terminal Odd B of the first shift register unit GOA1 outputs a conduction level with a duration of T, the second selection terminal Even_B of the second shift register unit GOA2 sequentially outputs a non-conduction level and a conduction level, each with a duration of T/2.

Furthermore, each of the duration of the conduction level at the first clock signal terminal CK and the duration of the conduction level at the second clock signal terminal CB is t, where t=T/2.

Furthermore, when the input terminal Input of the first shift register unit GOAL is at a conduction level, the first clock signal terminal CK of the first shift register unit GOA1 is at a conduction level, and the second clock signal terminal CB is at a non-conduction level.

As shown in FIG. 5, in a first gating phase T1, the first selection terminal Odd A of the first shift register unit GOA1 is at a low level, and the second selection terminal Odd B is at a high level. The first selection transistor TS1 and the third selection transistor TS3 in the first shift register unit GOA1 are turned on, and the second selection transistor TS2 and the fourth selection transistor TS4 are turned off.

As shown in FIGS. 5 and 6, in the first phase t1, in the first shift register unit GOA1, the input terminal Input is at a low level. Therefore, the first selection transistor TS1 transmits the low-level signal from the input terminal Input to the first node N1, causing the first node N1 to be at a low level. In the first phase t1, the first clock signal terminal CK of the first shift register unit GOA1 is at a low level, and the second clock signal terminal CB is at a high level. Thus, the first transistor T1 is turned on, to transmit the low-level signal from the first node N1 to the third node N3, causing the third node N3 to be at the low level.

As shown in FIG. 6, under the control of the low-level signal at the first clock signal terminal CK, the first control transistor TD is turned on, and the first level signal VGL pulls the second node N2 low, i.e., the second node N2 becomes to be at a low level. Under the control of the low-level signal at the second node N2, the first output transistor TO1 and the second output transistor TO2 are turned on, to transmit the second level signal VGH to the first output terminal Out1 and the second output terminal Out2. Therefore, both the first output terminal Out1 and the second output terminal Out2 of the first shift register unit GOA1 output high-level signals during this phase, i.e., the first output terminal G-out1 and the third output terminal G-out3 of the gate driving circuit both output high-level signals.

Meanwhile, during this first phase t1, as shown in FIG. 7, in the second shift register unit GOA2, the first selection terminal Even_A is at a high level, the second selection terminal Even B is at a low level, the first clock signal terminal CK is at a high level, and the second clock signal terminal CB is at a low level. The first selection transistor TS1 and the third selection transistor TS3 are turned off, while the second selection transistor TS2 and the fourth selection transistor TS4 are turned on. The second selection transistor TS2 transmits the signal from the feedback terminal FB, i.e., the second output terminal Out2 of the first shift register unit GOA1, to the first node N1. Thus, the first node N1 of the second shift register unit GOA2 becomes to be at a high level. Meanwhile, the first transistor T1 and the first control transistor TD are turned off, the second node N2 maintains the low-level signal from the previous phase, and the third node N3 maintains the high-level signal from the previous phase.

As shown in FIG. 7, under the low-level signal at the second node N2, the first output transistor TO1 and the second output transistor TO2 in the second shift register unit GOA2 are turned on, transmitting the second level signal VGH to the first output terminal Out1 and the second output terminal Out2. Therefore, during this phase, both the second output terminal G-out2 and the fourth output terminal G-out4 of the gate driving circuit output high-level signals.

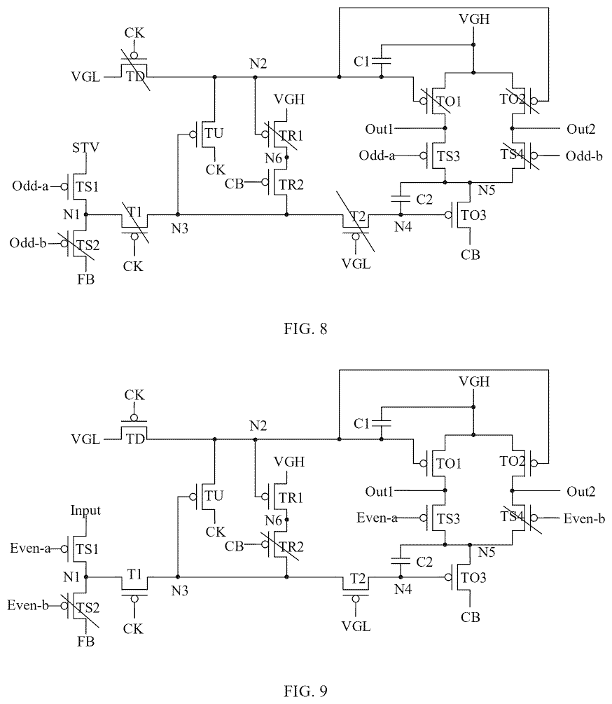

In the second phase t2, in the first shift register unit GOA1, the first selection terminal Odd_A is at a low level, the second selection terminal Odd_B is at a high level, the first clock signal terminal CK is at a high level, and the second clock signal terminal CB is at a low level. In the second shift register unit GOA2, the first selection terminal Even Ais at a low level, the second selection terminal Even_B is at a high level, the first clock signal terminal CK is at a low level, and the second clock signal terminal CB is at a high level. FIG. 8 shows an equivalent circuit diagram of a first shift register unit in a second phase, and FIG. 9 shows an equivalent circuit diagram of a second shift register unit in a second phase.

As shown in FIG. 8, the first selection transistor TS1 and the third selection transistor TS3 are turned on, and the second selection transistor TS2 and the fourth selection transistor TS4 are turned off. The first transistor T1 and the first control transistor TD are turned off, the third node N3 maintains the low-level signal from the previous phase, and the second control transistor TU is turned on, transmitting the high-level signal from the first clock signal terminal CK to the second node N2. Thus, the second node N2 becomes to be at a high level.

As shown in FIG. 8, the second transistor T2 is turned on, such that the fourth node N4 and the third node N3 are at the same potential, both being at a low level. Under the control of the low-level signal at the fourth node N4, the third output transistor TO3 is turned on, transmitting the low-level signal from the second clock signal terminal CB to the fifth node N5, causing the fifth node N5 to become a low level. Additionally, both the fourth node N4 and the second clock signal terminal CB are at low levels, and the second capacitor C2 performs bootstrapping, further pulling the potential of the fourth node N4 lower. Thus, a gate-source voltage Vgs of the second transistor T2 is greater than Vth, causing the second transistor T2 to be turned off.

As shown in FIG. 8, under the control of the low-level signal at the first selection terminal Odd_A, the third selection transistor TS3 is turned on, transmitting the low-level signal from the fifth node N5 to the first output terminal Out1, such that the first output terminal Out1 outputs a low-level signal at this time. Both the second output transistor TO2 and the fourth selection transistor TS4 are turned off, such that the second output terminal Out2 maintains the output of the high-level signal. Therefore, the first output terminal G-out1 of the gate driving circuit outputs the low-level signal at this time, achieving a first shift signal output.

In the second phase t2, as shown in FIG. 9, in the second shift register unit GOA2, the first selection terminal Even_A is at a low level, the second selection terminal Even B is at a high level, the first clock signal terminal CK is at a low level, and the second clock signal terminal CB is at a high level. The first selection transistor TS1 and the third selection transistor TS3 are turned on, and the second selection transistor TS2 and the fourth selection transistor TS4 are turned off, thereby transmitting the low-level signal from the input terminal Input, i.e., the first output terminal Out1 of the first shift register unit GOA1, to the first node N1, causing the first node N1 to become a low level.

As shown in FIG. 9, under the control of the low-level signal at the first clock signal terminal CK, the first transistor T1 and the first control transistor TD are turned on, such that the second node N2 and the third node N3 are both at low levels.

As shown in FIG. 9, under the control of the low-level signal at the second node N2, the first output transistor TO1 and the second output transistor TO2 are turned on, causing the first output terminal Out1 and the second output terminal Out2 of the second shift register unit GOA2 to output high-level signals, i.e., the second output terminal G-out2 and the fourth output terminal G-out4 of the gate driving circuit output high-level signals at this time.

In a second gating phase T2, the first selection terminal Odd A of the first shift register unit GOA1 is at a high level, the second selection terminal Odd_B is at a low level, the first selection transistor TS1 and the third selection transistor TS3 of the first shift register unit GOA1 are turned off, and the second selection transistor TS2 and the fourth selection transistor TS4 are turned on.

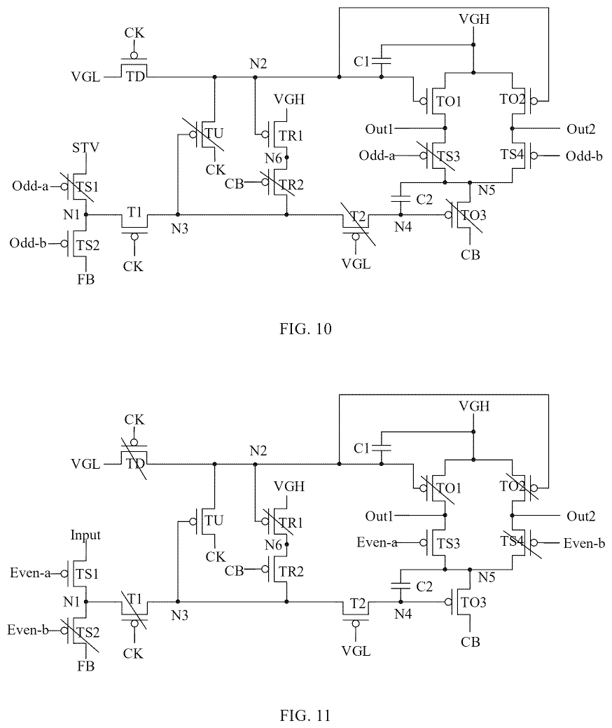

FIG. 10 is an equivalent circuit diagram of a first shift register unit in a third phase, and FIG. 11 is an equivalent circuit diagram of a second shift register unit in a third phase.

As shown in FIG. 10, in the third phase t3, in the first shift register unit GOA1, the first clock signal terminal CK is at a low level, and the second clock signal terminal CB is at a high level. Thus, the first transistor T1 and the first control transistor TD are turned on, and the third node N3 and the first node N1 at the same potential, both at the high-level signal output from the second output terminal G-out2 of the gate driving circuit. The second node N2 is pulled down to a low level by the first level signal VGL.

As shown in FIG. 10, under the control of the low-level signal at the second node N2, the first output transistor TO1 and the second output transistor TO2 are turned on, causing the first output terminal Out1 and the second output terminal Out2 to both output the second level signal VGH, i.e., the first output terminal G-out1 and the third output terminal G-out3 of the gate driving circuit both output high-level signals at this time. The second transistor T2 remains in an off state, and during this process, the second level signal VGH charges the fifth node N5 via the fourth selection transistor TS4, causing the potential of the fifth node N5 to gradually decrease.

In the third phase t3, as shown in FIG. 11, in the second shift register unit GOA2, the first selection terminal Even_A is at a low level, the second selection terminal Even_B is at a high level, the first clock signal terminal CK is at a high level, and the second clock signal terminal CB is at a low level. Thus, the first selection transistor TS1 and the third selection transistor TS3 are turned on, while the second selection transistor TS2 and the fourth selection transistor TS4 are turned off. The first clock signal terminal CK is at a high level, causing the first transistor T1 and the first control transistor TD to be turned off, and the third node N3 maintains at the low level from the previous phase. The second control transistor TU is turned on under the control of the low-level signal at the third node N3, transmitting the high-level signal from the first clock signal terminal CK to the second node N2, causing the second node N2 to become a high level, and both the first output transistor TO1 and the second output transistor TO2 are turned off.

Additionally, as shown in FIG. 10, the third output transistor TO3 is turned off, and the fifth node N5 maintains at the low level from the previous phase.

As shown in FIG. 11, the second transistor T2 is turned on, causing the fourth node N4 to be at a low level. Under the control of the low-level signal at the fourth node N4, the third output transistor TO3 is turned on, transmitting the low-level signal from the second clock signal terminal CB to the fifth node N5, causing the fifth node N5 to become a low level. The third selection transistor TS3, which is turned on, transmits the low-level signal from the fifth node N5 to the first output terminal Out1, such that the first output terminal Out1 outputs a low-level signal at this time, and thus the second output terminal G-out2 of the gate driving circuit outputs a low-level signal and the fourth output terminal outputs a high-level signal, achieving a second shift signal output.

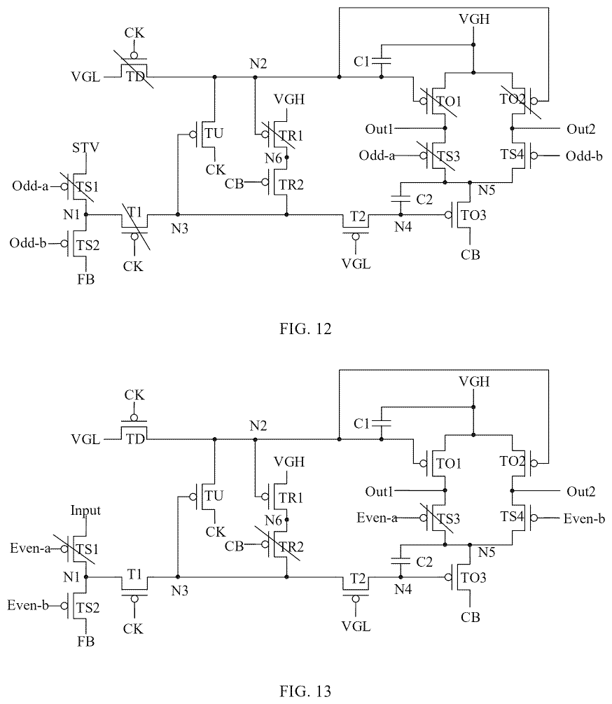

In the fourth phase t4, in the first shift register unit GOA1, the first selection terminal Odd_A is at a high level, the second selection terminal Odd_B is at a low level, the first clock signal terminal CK is at a high level, and the second clock signal terminal CB is at a low level. In the second shift register unit GOA2, the first selection terminal Even A is at a high level, the second selection terminal Even_B is at a low level, the first clock signal terminal CK is at a low level, and the second clock signal terminal CB is at a high level. FIG. 12 shows an equivalent circuit diagram of a first shift register unit in a fourth phase, and FIG. 13 shows an equivalent circuit diagram of a second shift register unit in a fourth phase.

As shown in FIG. 12, the first selection transistor TS1 and the third selection transistor TS3 are turned off, while the second selection transistor TS2 and the fourth selection transistor TS4 are turned on. The first transistor T1 and the first control transistor TD are both turned off. During this process, the potential of the fifth node N5 decreases, which causes the potential of the fourth node N4 to decrease, thereby turning on the second transistor T2, which transmits the low-level signal from the fourth node N4 to the third node N3, causing the third node N3 to be at a low level. Under the control of the low-level signal at the third node N3, the second control transistor TU is turned on, pulling the second node N2 high, such that the second node N2 becomes a high level, and both the first output transistor TO1 and the second output transistor TO2 are turned off.

Under the low-level control of the fourth node N4, the third output transistor TO3 is turned on, transmitting the low-level signal from the second clock signal terminal CB to the fifth node N5, such that the fourth selection transistor TS4 outputs the low-level signal from the fifth node N5. That is, the third output terminal G-out3 of the gate driving circuit outputs a low-level signal at this time, thus achieving a third shift signal output.

As shown in FIG. 13, in the fourth phase t4, in the second shift register unit GOA2, the first selection terminal Even_A becomes a high level, the second selection terminal Even B becomes a low level, the first clock signal terminal CK is at a low level, and the second clock signal terminal CB is at a high level.

As shown in FIG. 13, the first selection transistor TS1 and the third selection transistor TS3 are turned off, while the second selection transistor TS2 and the fourth selection transistor TS4 are turned on. The first transistor T1 and the first control transistor TD are turned on. The second selection transistor TS2 transmits the low-level signal from the feedback terminal FB, i.e., the third output terminal Out3 of the gate driving circuit, to the first node N1, causing the first node N1 to become a low level. The first transistor T1 transmits the low-level signal from the first node N1 to the third node N3, making the third node N3 a low level. The first control transistor TD is turned on to transmit the first level signal VGL to the second node N2, causing the second node N2 to become a low level.

As shown in FIG. 13, under the low-level signal at the second node N2, the first output transistor TO1 and the second output transistor TO2 are turned on, transmitting the second level signal VGH to the first output terminal Out1 and the second output terminal Out2 for output. Therefore, both the first output terminal Out1 and the third output terminal Out3 of the gate driving circuit output high-level signals at this time.

In a third gating phase T3, in the first shift register unit GOA1, the first selection terminal Odd_A is at a low level, the second selection terminal Odd_B is at a high level. Therefore, the first selection transistor TS1 and the third selection transistor TS3 are turned on, and the second selection transistor TS2 and the fourth selection transistor TS4 are turned off.

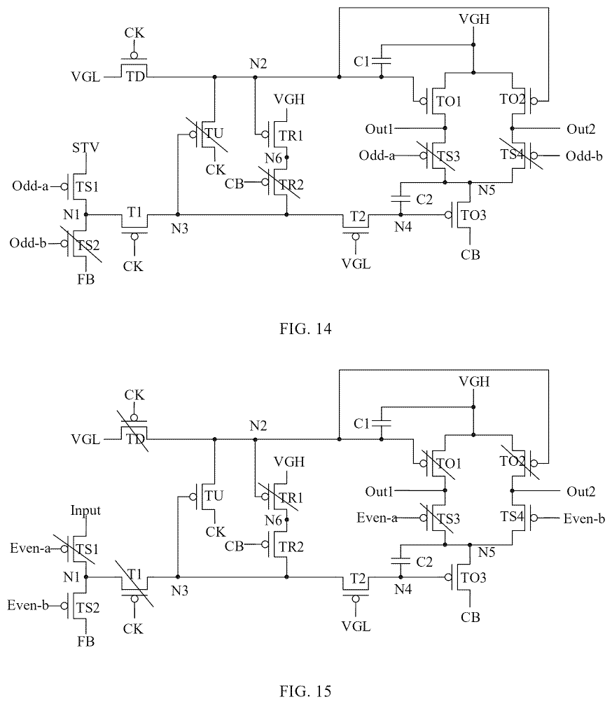

FIG. 14 is an equivalent circuit diagram of a first shift register unit in a fifth phase, and FIG. 15 is an equivalent circuit diagram of a second shift register unit in a fifth phase.

As shown in FIG. 14, in the fifth phase t5, in the first shift register unit GOA1, the first clock signal terminal CK is at a low level, and the second clock signal terminal CB is at a high level. Thus, the first transistor T1 and the first control transistor TD are turned on. The first transistor T1 is turned on to use the high-level signal from the first node N1 to pull the third node N3 high, such that the third node N3 becomes high at this time. The first control transistor TD is turned on to use the first level signal VGL to pull the second node N2 down, causing the second node N2 to become low at this time.

As shown in FIG. 14, under the control of the low-level signal at the second node N2, both the first output transistor TO1 and the second output transistor TO2 are turned on, causing both the first output terminal Out and the second output terminal Out2 to output the second level signal VGH, i.e., both the first output terminal G-out1 and the third output terminal G-out3 of the gate driving circuit output high-level signals at this time.

As shown in FIG. 15, in the second shift register unit GOA2, the first selection terminal Even_A is at a high level, the second selection terminal Even_B is at a low level, and thus the first selection transistor TS1 is turned off, and the second selection transistor TS2 is turned on. The first clock signal terminal CK is at a high level, and the second clock signal terminal CB is at a low level, and thus the first transistor T1 and the first control transistor TD are both turned off, and the third node N3 maintains the low-level signal from the previous phase. Under the low-level signal at the third node N3, the second control transistor TU is turned on, transmitting the high-level signal from the first clock signal terminal CK to the second node N2, causing the second node N2 to become to be at the high level at this time. Thus, both the first output transistor TO1 and the second output transistor TO2 are turned off.

As shown in FIG. 15, the fourth node N4 is at a low level, and thus the third output transistor TO3 is turned on, transmitting the low-level signal from the second clock signal terminal CB to the fifth node N5, causing the fifth node N5 to become to be at the low level at this time. Therefore, the turned-on fourth selection transistor TS4 transmits the low-level signal from the fifth node N5 to the second output terminal Out2, such that the fourth output terminal G-out4 of the gate driving circuit outputs a low-level signal, achieving a fourth shift output of the shift register unit.

Thus, after a complete cycle of the first phase t1 to the fifth phase t5, the first output terminal Out1, the second output terminal Out2, the third output terminal Out3, and the fourth output terminal of the gate driving circuit output low-level signals sequentially, achieving the sequential shift output of the signal from the input terminal Input. After that, the gate driving circuit repeats the above process, sequentially outputting the shift signal.

As can be seen, in the gate driving circuit of the present disclosure, the first shift register unit GOA1 and the second shift register unit GOA2 may each output two rows of gate signals. One first shift register unit GOA1 and one second shift register unit GOA2 form one repeating unit Q. Therefore, one repeating unit Q may output four rows of gate signals to the display region.

According to the second aspect of the present disclosure, a display panel is further provided, which includes the gate driving circuit described in any of the embodiments of the present disclosure.

Those skilled in the art, after considering the specification and practicing the invention disclosed herein, will readily conceive of other embodiments of the present disclosure. The present disclosure is intended to cover any modifications, uses, or adaptations of the present disclosure, and these modifications, uses, or adaptations are within the general scope of the disclosure, including those not specifically disclosed herein but which are common knowledge or conventional techniques in the technical field. The specification and embodiments are to be regarded as exemplary only, and the true scope and spirit of the present disclosure are defined by the claims.

1. A gate driving circuit, comprising a plurality of repeating units, wherein the repeating unit comprise a first shift register unit and a second shift register unit connected in cascade, each of the first shift register unit and the second shift register unit comprise an input selection module, an output selection module, one input terminal, one feedback terminal, and two output terminals, and the first shift register unit and the second shift register unit are each respectively connected to a first clock signal terminal and a second clock signal terminal;
in a same repeating unit, the feedback terminal of the first shift register unit is connected to a first output terminal of the second shift register unit, a first output terminal of the first shift register unit is connected to the input terminal of the second shift register unit, and a second output terminal of the first shift register unit is connected to the feedback terminal of the second shift register unit;
in two adjacent repeating units, a second output terminal of the second shift register unit in a previous repeating unit is connected to the input terminal of the first shift register unit in a next repeating unit;
in a same shift register unit, the input selection module is connected to the input terminal, a first selection terminal, a second selection terminal, and the feedback terminal; and the input selection module is configured to use a signal of the input terminal for input in response to a signal of the first selection terminal or to use a signal of the feedback terminal for input in response to a signal of the second selection terminal; the output selection module is connected to the first output terminal, the second output terminal, the first selection terminal, and the second selection terminal, and the output selection module is configured to perform an output operation through the first output terminal in response to the signal of the first selection terminal, or to perform an output operation through the second output terminal in response to the signal of the second selection terminal;
wherein in the same shift register unit, the signal of the first selection terminal and the signal of the second selection terminal are of opposite polarities, and conduction levels of the first selection terminals of two shift register units in the same repeating unit are partially overlapped with each other, and conduction levels of the second selection terminals of the two shift register units in the same repeating unit are partially overlapped with each other;
a signal of the first clock signal terminal is inverted to a signal of the second clock signal terminal, and signals of the first clock signal terminal and the second clock signal terminal of the first shift register unit are correspondingly inverted to signals of the first clock signal terminal and the second clock signal terminal of the second shift register unit.

2. The gate driving circuit according to claim 1, wherein in any one of the repeating units, the first output terminal of the first shift register unit is served as an nth output terminal of the gate driving circuit, and the second output terminal of the first shift register unit is served as an (n+2)th output terminal of the gate driving circuit;
the first output terminal of the second shift register unit is served as an (n+1)th output terminal of the gate driving circuit, and the second output terminal of the second shift register unit is served as an (n+3)th output terminal of the gate driving circuit, where n is a natural number greater than or equal to 1.

3. The gate driving circuit according to claim 1, wherein when the first selection terminal of the first shift register unit outputs a conduction level with a duration of T, the first selection terminal of the second shift register unit sequentially outputs a conduction level with a duration of T/2 and a non-conduction level with a duration of T/2;
when the second selection terminal of the first shift register unit outputs a conduction level with a duration of T, the second selection terminal of the second shift register unit sequentially outputs a non-conduction level with a duration of T/2 and a conduction level with a duration of T/2.

4. The gate driving circuit according to claim 3, wherein a duration of a conduction level of the first clock signal terminal and a duration of a conduction level of the second clock signal terminal are t, where t=T/2.

5. The gate driving circuit according to claim 1, wherein when the input terminal of the first shift register unit is at a conduction level, the first clock signal terminal of the first shift register unit is at a conduction level, and the second clock signal terminal of the first shift register unit is at a non-conduction level.

6. The gate driving circuit according to claim 1, wherein the input selection module is further connected to a first node, and the input selection module is further configured to transmit the signal of the input terminal to the first node in response to the signal of the first selection terminal, or to transmit the signal of the feedback terminal to the first node in response to the signal of the second selection terminal; and
the output selection module is further connected to a fifth node, and the output selection module is further configured to transmit a signal of the fifth node to the first output terminal in response to the signal of the first selection terminal, or to transmit a signal of the fifth node to the second output terminal in response to the signal of the second selection terminal.

7. The gate driving circuit according to claim 6, wherein each of the input selection module and the output selection module comprises a transistor, and a polarity of each transistor is identical.

8. The gate driving circuit according to claim 6, wherein the input selection module comprises:
a first selection transistor, with a first electrode connected to the input terminal, a second electrode connected to the first node, and a gate connected to the first selection terminal, wherein the first selection transistor is configured to transmit the signal of the input terminal to the first node in response to the signal of the first selection terminal;
a second selection transistor, with a first electrode connected to the feedback terminal, a second electrode connected to the first node, and a gate connected to the second selection terminal, wherein the second selection transistor is configured to transmit the signal of the feedback terminal to the first node in response to the signal of the second selection terminal;
wherein the output selection module comprises:
a third selection transistor, with a first electrode connected to the fifth node, a second electrode connected to the first output terminal, and a gate connected to the first selection terminal, wherein the third selection transistor is configured to transmit the signal of the fifth node to the first output terminal in response to the signal of the first selection terminal;
a fourth selection transistor, with a first electrode connected to the fifth node, a second electrode connected to the second output terminal, and a gate connected to the second selection terminal, wherein the fourth selection transistor is configured to transmit the signal of the fifth node to the second output terminal in response to the signal of the second selection terminal;
wherein the first selection transistor, the second selection transistor, the third selection transistor and the fourth selection transistor are all P-type transistors.

9. The gate driving circuit according to claim 1, wherein the first shift register unit and the second shift register unit each comprise:
an input module, connected to a first node, a third node, and the first clock signal terminal, wherein the input module is configured to transmit a signal of the first node to the third node in response to the signal of the first clock signal terminal;
a first control module, connected to a second node and the first clock signal terminal, and configured to receive a first level signal, wherein the first control module is configured to pull down the second node using the first level signal in response to the signal of the first clock signal terminal;
a second control module, connected to the second node, the third node, and the first clock signal terminal, wherein the second control module is configured to pull up the second node using the signal of the first clock signal terminal in response to a signal of the third node;
a reset module, connected to the second node, the third node, and the second clock signal terminal, and receiving a second level signal, wherein the reset module is configured to reset the third node using the second level signal in response to a signal of the second node and the signal of the second clock signal terminal;
a protection module, connected to the third node and a fourth node, and receiving the first level signal, wherein the protection module is configured to transmit the signal of the third node to the fourth node in response to the first level signal, or to be turned off in response to a voltage difference between the first level signal and a signal of the fourth node;
a first output module, connected to the second node, the first output terminal and the second output terminal, and receiving the second level signal, wherein the first output module is configured to transmit the second level signal to the first output terminal and the second output terminal in response to the signal of the second node;
a second output module, connected to a fifth node, the fourth node, and the second clock signal terminal, wherein the second output module is configured to transmit the signal of the second clock signal terminal to the fifth node in response to the signal of the fourth node.

10. The gate driving circuit according to claim 9, wherein the input module, the first control module, the second control module, the reset module, the protection module, the first output module, and the second output module each comprise a transistor, and a polarity of each transistor is identical.

11. The gate driving circuit according to claim 9, wherein the input module comprises:
a first transistor, with a first electrode connected to the first node, a second electrode connected to the third node, and a gate connected to the first clock signal terminal, wherein the first transistor is configured to transmit the signal of the first node to the third node in response to the signal of the first clock signal terminal;
a first control transistor, with a first electrode configured to receive the first level signal, a second electrode connected to the second node, and a gate connected to the first clock signal terminal, wherein the first control transistor is configured to transmit the first level signal to the second node in response to the signal of the first clock signal terminal;
wherein the second control module comprises:
a second control transistor, with a first electrode connected to the second node, a second electrode connected to the first clock signal terminal, and a gate connected to the third node, wherein the second control transistor is configured to pull down the second node using the signal of the first clock signal terminal in response to the signal of the third node;
wherein the reset module comprises:
a first reset transistor, with a first electrode is connected to receive the second level signal, a second electrode connected to a sixth node, and a gate connected to the second node, wherein the first reset transistor is configured to transmit the second level signal to the sixth node in response to the signal of the second node;
a second reset transistor, with a first electrode connected to the third node, a second electrode connected to the sixth node, and a gate connected to the second clock signal terminal, wherein the second reset transistor is configured to transmit, in response to the signal of the second clock signal terminal, a signal of the sixth node to the third node to reset the third node;
wherein the protection module comprises:
a second transistor, with a first electrode connected to the third node, a second electrode connected to the fourth node, and a gate configured to receive the first level signal, wherein the second transistor is configured to transmit the signal of the third node to the fourth node in response to the first level signal, or to be turned off in response to the voltage difference between the first level signal and the signal of the fourth node;
wherein the first output module comprises:
a first output transistor, with a first electrode configured to receive the second level signal, a second electrode connected to the first output terminal, and a gate connected to the second node, wherein the first output transistor is configured to transmit the second level signal to the first output terminal in response to the signal of the second node;
a second output transistor, with a first electrode configured to receive the second level signal, a second electrode connected to the second output terminal, and a gate connected to the second node, wherein the second output transistor is configured to transmit the second level signal to the second output terminal in response to the signal of the second node;
wherein the second output module comprises:
a third output transistor, with a first electrode connected to the fifth node, a second electrode connected to the second clock signal terminal, and a gate connected to the fourth node, wherein the third output transistor is configured to transmit the signal of the second clock signal terminal to the fifth node in response to the signal of the fourth node.

12. The gate driving circuit according to claim 11, wherein the first transistor, the first control transistor, the second control transistor, the first reset transistor, the second reset transistor, the second transistor, the first output transistor, the second output transistor, and the third output transistor are all P-type transistors.

13. The gate driving circuit according to claim 1, wherein the first shift register unit and the second shift register unit each further comprise:
a first storage module, connected to a second node and receiving a second level signal, wherein the first storage module is configured to maintain stability of a potential of the second node;
a second storage module, connected to a fourth node and a fifth node, wherein the second storage module is configured to bootstrap the fourth node when a polarity for a signal of the fifth node and a polarity for a signal of the fourth node are identical.

14. The gate driving circuit according to claim 13, wherein the first storage module comprises:
a first capacitor, with a first terminal connected to the second node, and a second terminal configured to receive the second level signal;
wherein the second storage module comprises:
a second capacitor, with a first terminal connected to the fourth node and a second terminal connected to the fifth node.

15. A display panel, comprising a gate driving circuit; wherein the gate driving circuit comprises a plurality of repeating units, wherein the repeating unit comprise a first shift register unit and a second shift register unit connected in cascade, each of the first shift register unit and the second shift register unit comprise an input selection module, an output selection module, one input terminal, one feedback terminal, and two output terminals, and the first shift register unit and the second shift register unit are each respectively connected to a first clock signal terminal and a second clock signal terminal;
in a same repeating unit, the feedback terminal of the first shift register unit is connected to a first output terminal of the second shift register unit, a first output terminal of the first shift register unit is connected to the input terminal of the second shift register unit, and a second output terminal of the first shift register unit is connected to the feedback terminal of the second shift register unit;
in two adjacent repeating units, a second output terminal of the second shift register unit in a previous repeating unit is connected to the input terminal of the first shift register unit in a next repeating unit;
in a same shift register unit, the input selection module is connected to the input terminal, a first selection terminal, a second selection terminal, and the feedback terminal; and the input selection module is configured to use a signal of the input terminal for input in response to a signal of the first selection terminal or to use a signal of the feedback terminal for input in response to a signal of the second selection terminal; the output selection module is connected to the first output terminal, the second output terminal, the first selection terminal, and the second selection terminal, and the output selection module is configured to perform an output operation through the first output terminal in response to the signal of the first selection terminal, or to perform an output operation through the second output terminal in response to the signal of the second selection terminal;
wherein in the same shift register unit, the signal of the first selection terminal and the signal of the second selection terminal are of opposite polarities, and conduction levels of the first selection terminals of two shift register units in the same repeating unit are partially overlapped with each other, and conduction levels of the second selection terminals of the two shift register units in the same repeating unit are partially overlapped with each other;
a signal of the first clock signal terminal is inverted to a signal of the second clock signal terminal, and signals of the first clock signal terminal and the second clock signal terminal of the first shift register unit are correspondingly inverted to signals of the first clock signal terminal and the second clock signal terminal of the second shift register unit.

16. The display panel according to claim 15, wherein in any one of the repeating units, the first output terminal of the first shift register unit is served as an nth output terminal of the gate driving circuit, and the second output terminal of the first shift register unit is served as an (n+2)th output terminal of the gate driving circuit;
the first output terminal of the second shift register unit is served as an (n+1)th output terminal of the gate driving circuit, and the second output terminal of the second shift register unit is served as an (n+3)th output terminal of the gate driving circuit, where n is a natural number greater than or equal to 1.

17. The display panel according to claim 15, wherein when the first selection terminal of the first shift register unit outputs a conduction level with a duration of T, the first selection terminal of the second shift register unit sequentially outputs a conduction level with a duration of T/2 and a non-conduction level with a duration of T/2;
when the second selection terminal of the first shift register unit outputs a conduction level with a duration of T, the second selection terminal of the second shift register unit sequentially outputs a non-conduction level with a duration of T/2 and a conduction level with a duration of T/2.

18. The display panel according to claim 17, wherein a duration of a conduction level of the first clock signal terminal and a duration of a conduction level of the second clock signal terminal are t, where t=T/2.

19. The display panel according to claim 15, wherein when the input terminal of the first shift register unit is at a conduction level, the first clock signal terminal of the first shift register unit is at a conduction level, and the second clock signal terminal of the first shift register unit is at a non-conduction level.

20. The display panel according to claim 15, wherein the input selection module is further connected to a first node, and the input selection module is further configured to transmit the signal of the input terminal to the first node in response to the signal of the first selection terminal, or to transmit the signal of the feedback terminal to the first node in response to the signal of the second selection terminal; and
the output selection module is further connected to a fifth node, and the output selection module is further configured to transmit a signal of the fifth node to the first output terminal in response to the signal of the first selection terminal, or to transmit a signal of the fifth node to the second output terminal in response to the signal of the second selection terminal.
